(19) United States
(12) Patent Application Publication
(10) Pub. No.: US 2017/0267542 A1
(43) Pub. Date: Sep. 21, 2017

(54) SYNTHESIS METHOD FOR TIO2 NANOCRYSTAL

(71) Applicants: BEIJING NORMAL UNIVERSITY, Beijing (CN); BEIJING NORMAL UNIVERSITY SCIENCE PARK CO., LTD., Beijing (CN)

(72) Inventors: Xiaojing Yang, Beijing (CN); Yien Du, Beijing (CN); Dejian Du, Beijing (CN)

(21) Appl. No.: 15/505,025

(22) PCT Filed: May 29, 2015
(86) PCT No.: PCT/CN2015/080268

§ 371 Date: Feb. 17, 2017

(30) Foreign Application Priority Data
Aug. 20, 2014 (CN) 201410410548.3

(51) Int. Cl. C01G 23/053; C30B 29/16; C30B 7/10

(52) U.S. Cl. CPC C01G 23/053; C30B 7/10; C30B 29/16; C01P 2002/72; C01P 2004/03; C01P 2004/64

(57) ABSTRACT

Provided is a method for synthesizing TiO₂ nanocrystal, comprising: adjusting the pH value of a colloidal suspension of tetratitanic acid nanosheet as a precursor to 5-13; and subjecting the precursor to a hydrothermal reaction to obtain the TiO₂ nanocrystal. The TiO₂ nanocrystal synthesized by the method is anatase-type, and the exposed crystal facet thereof is {010} crystal facet. The method has advantages of low cost, no pollution, simple synthesizing process, strong controllability, short production period and good reproducibility, and is suitable for industrial production.

### TECHNICAL FIELD

The present invention relates to the field of crystal materials, and particularly relates to a method for synthesizing TiO₂ nanocrystal.

### BACKGROUND ART

In 1972, Honda and Fujishima, Japan, found that TiO₂ (titanium dioxide) nanocrystal can split of water into H₂ and O₂ under ultraviolet irradiation. Since then, TiO₂ nanocrystal has drawn much attention of researchers at home and abroad, and was intensively studied.

TiO₂ nanocrystal has some outstanding features, such as highly stable, non-toxic, environmental benignity, and low cost. It is not only widely used for producing hydrogen by the photolysis of water, but also widely used in the fields of dye-sensitized solar cell, the photocatalytic degradation of toxic pollutant, energy storage and conversion, electrochromism, sensing, and the like. Since the exposed crystal facet of TiO₂ nanocrystal strongly affects the photocatalytic property and photovoltaic property thereof, it is very important to synthesize anatase-type TiO₂ nanocrystal with specific exposed crystal facet.

In recent years, it is noticed that {010} crystal facet has superior surface atomic structure and electronic structure, since the synergistic effect of the surface atomic structure and electronic structure allows {010} crystal facet to exhibit the highest reaction activity. Therefore, it is at present a research focus in the fields of photocatalysis and solar cell to produce an anatase-type nanocrystal material having {010} crystal facet with high reaction activity.

Now, there have been some reports on methods for synthesizing an anatase-type TiO₂ nanocrystal which preferentially exposes {010} crystal facet. In these reported synthesis methods, the titanium material used is primarily organic titanate. The hydrolysis rate of organic titanate is too fast to control in the experimental process. And organic titanate is deliquescent and very inconvenient for transportation and storage since it is in liquid state. Also the price of organic titanate is relatively high, rendering the price of the obtained product being relatively high, so that it is difficult to realize industrial production.

The anatase-type TiO₂ with {010} crystal facet synthesized by these reported synthesis method also has some disadvantages in catalytic applications.

Firstly, some organic compounds or inorganic compounds usually cover the {010} crystal facet of the synthesized anatase-type TiO₂ nanocrystal, which can significantly reduce the catalytic property thereof. Secondly, in the synthesized anatase-type TiO₂ nanocrystal, the proportion of the {010} crystal facet thereof is relatively low. This limits the large scale production and application for the produced anatase-type TiO₂ nanocrystal with {010} crystal facet.

Thus, the green synthesis of anatase-type TiO₂ nanocrystal with relatively high proportion of clean {010} crystal facet is very necessary.

### SUMMARY OF THE INVENTION

To solve the above-mentioned problems, the embodiments of the present invention disclose a method for synthesizing TiO₂ nanocrystal. The present technical solution is as follows:

a method for synthesizing TiO₂ nanocrystal, which can comprise the following steps:

adjusting the pH value of a colloidal suspension of tetratitanic acid nanosheet as a precursor to 5-13; and

subjecting the precursor with a pH value of 5-13 to a hydrothermal reaction to obtain the TiO₂ nanocrystal.

In the method, after the hydrothermal reaction, the obtained product is separated, washed, filtered and dried.

In one preferable embodiment of the present invention, the step of subjecting the precursor with a pH of 5-13 to a hydrothermal reaction is as follows:

applying a microwave radiation to the precursor with a pH value of 5-13 for 1 to 2 hours at 160 to 200° C.; or

heating the precursor with a pH value of 5-13 to 140 to 200° C. and maintaining the temperature for 18 to 30 hours.

In one preferable embodiment of the present invention, the pH value of the precursor is adjusted with a first hydrochloric acid solution and a first tetramethylammonium hydroxide solution, wherein the concentration of the first hydrochloric acid solution is 1 mol/L to 3 mol/L, and the concentration of the first tetramethylammonium hydroxide solution is 0.5 mol/L to 2 mol/L.

In one preferable embodiment of the present invention, the method for preparing the colloidal suspension of tetratitanic acid nanosheet as precursor comprises the following steps:

a) synthesizing a lamellar potassium tetratitanate:

K₂CO₃ and anatase-type TiO₂ as raw materials are homogeneously mixed, heated to 800 to 1000° C., and reacted for 20 to 30 hours, obtaining lamellar potassium tetratitanate, wherein the molar ratio of the K₂CO₃ and anatase-type TiO₂ is (1-1.1):4;

b) synthesizing a tetratitanic acid:

the potassium tetratitanate synthesized in step a) is dissolved in a second hydrochloric acid solution to perform a proton exchange reaction, the obtained product is separated after the completion of the reaction, and then the obtained product is washed, filtered and dried, obtaining the tetratitanic acid; and

c) synthesizing the colloidal suspension of tetratitanic acid nanosheet:

the tetratitanic acid synthesized in step b) is added into a second tetramethylammonium hydroxide solution, obtaining a mixed solution; the mixed solution is subjected to reaction for 20 to 30 hours at 90 to 110° C.; after the completion of the reaction, the obtained product is mixed with water, stirred, and then filtered after standing, obtaining the colloidal suspension of protonic tetratitanate nanosheet as precursor.

In one preferable embodiment of the present invention, in step a), after mixing K₂CO₃ and anatase-type TiO₂ homogeneously and prior to heating to 800 to 1000° C., it further comprises grinding sufficiently.

In one preferable embodiment of the present invention, in step a), the rate of the heating is 2° C./min to 8° C./min.

In one preferable embodiment of the present invention, in step b), the concentration of the second hydrochloric acid solution is 0.7 mol/L to 2 mol/L.

In one preferable embodiment of the present invention, in step b), the process of dissolving the potassium tetratitanate synthesized in step a) in a second hydrochloric acid to perform a proton exchange reaction is as follows:

the potassium tetratitanate synthesized in step a) is dissolved in the second hydrochloric acid, and stirred for 3 to 5 days, with the second hydrochloric acid changed once a day.

In one preferable embodiment of the present invention, in step c), the mass ratio of tetratitanic acid and tetramethylammonium hydroxide is 1: (1.2-3).

The present invention provides a method for synthesizing an anatase-type TiO₂ nanocrystal exposing {010} crystal facet. This method has advantages of low cost, no pollution, simple synthesizing process, strong controllability, short production period, good reproducibility, and is suitable for industrial production.

### BRIEF DESCRIPTION OF THE DRAWINGS

To illustrate the embodiments of the present invention or the technical solutions of the prior art more clearly, the drawings used in the description of the embodiments of the present invention or the technical solutions of the prior art will be described briefly below. Obviously, the drawings in the description below are only some examples of the present invention, and those of ordinary skill in the art can also obtain other drawings according to these drawings without inventive efforts.

FIG. 1 shows the XRD patterns of the potassium tetratitanate (K₂Ti₄O₉) synthesized in step a), the tetratitanic acid (H₂Ti₄O₉.0.25H₂O) synthesized in step b), tetramethylammonium ion (TMA⁺) intercalated tetratitanic acid (TMA⁺-intercalated H₂Ti₄O₉) and the nanoribbon-like tetratitanic acid exfoliated from the colloidal suspension of tetratitanic acid nanosheet synthesized in step c) in Example 1;

FIG. 2 shows the XRD patterns of the anatase-type TiO₂ nanocrystals synthesized in Examples 1 and 2, wherein (a) is the XRD pattern of the anatase-type TiO₂ nanocrystal synthesized in Example 1, and (b) is the XRD pattern of the anatase-type TiO₂ nanocrystal synthesized in Example 2;

FIG. 3 shows the XRD patterns of the anatase-type TiO₂ nanocrystals synthesized in Examples 4 to 8, wherein (a) is the XRD pattern of the anatase-type TiO₂ nanocrystal synthesized in Example 4, (b) is the XRD pattern of the anatase-type TiO₂ nanocrystal synthesized in Example 5, (c) is the XRD pattern of the anatase-type TiO₂ nanocrystal synthesized in Example 6, (d) is the XRD pattern of the anatase-type TiO₂ nanocrystal synthesized in Example 7, and (e) is the XRD pattern of the anatase-type TiO₂ nanocrystal synthesized in Example 8;

FIG. 4 shows the scanning electron microscope images of the anatase-type TiO₂ nanocrystals synthesized in Examples 1 to 3, wherein (a) is the scanning electron microscope image of the TiO₂ nanocrystal synthesized in Example 1, (b) is the scanning electron microscope image of the TiO₂ nanocrystal synthesized in Example 2, and (c) is the scanning electron microscope image of the TiO₂ nanocrystal synthesized in Example 3;

FIG. 5 shows the scanning electron microscope images of the anatase-type TiO₂ nanocrystals synthesized in Examples 4 to 8, wherein (a) is the scanning electron microscope image of the TiO₂ nanocrystal synthesized in Example 4, (b) is the scanning electron microscope image of the TiO₂ nanocrystal synthesized in Example 5, (c) is the scanning electron microscope image of the TiO₂ nanocrystal synthesized in Example 6, (d) is the scanning electron microscope image of the TiO₂ nanocrystal synthesized in Example 7, and (e) is the scanning electron microscope image of the TiO₂ nanocrystal synthesized in Example 8;

FIG. 6 shows the transmission electron microscope (TEM) images and the high resolution transmission electron microscope (HR-TEM) images of the anatase-type TiO₂ nanocrystals synthesized in Examples 1 and 2, wherein (a) is the transmission electron microscope image of the TiO₂ nanocrystal synthesized in Example 1, (b) is the high resolution transmission electron microscope image of the TiO₂ nanocrystal synthesized in Example 1, (c) is the transmission electron microscope image of the TiO₂ nanocrystal synthesized in Example 2, and (d) is the high resolution transmission electron microscope image of the TiO₂ nanocrystal synthesized in Example 2;

FIG. 7 shows the transmission electron microscope (TEM) images and the high resolution transmission electron microscope (HR-TEM) images of the anatase-type TiO₂ nanocrystals synthesized in Examples 5 and 6, wherein (a) is the transmission electron microscope image of the TiO₂ nanocrystal synthesized in Example 5, (b) is the high resolution transmission electron microscope image of the TiO₂ nanocrystal synthesized in Example 5, (c) is the transmission electron microscope image of the TiO₂ nanocrystal synthesized in Example 6, and (d) is the high resolution transmission electron microscope image of the TiO₂ nanocrystal synthesized in Example 6;

FIG. 8 is the characteristic curve of degradation efficiency versus irradiation time for the TiO₂ nanocrystal synthesized in Example 1;

FIG. 9 is the characteristic curve of degradation efficiency versus irradiation time for the TiO₂ nanocrystal synthesized in Example 2;

FIG. 10 is the characteristic curve of photocurrent versus voltage for the TiO₂ nanocrystal synthesized in Example 1; and

FIG. 11 is the characteristic curve of photocurrent versus voltage for the TiO₂ nanocrystal synthesized in Example 2.

### DETAILED DESCRIPTION OF THE INVENTION

In order to further illustrate the present invention, the technical solutions of the present invention will be described in combination with particular embodiments below. The described embodiments are only parts of the embodiments of the present invention, but not all of the embodiments. Based on the embodiments of the present invention, any other embodiments that obtained by those of ordinary skill in the art without inventive efforts fall within the protection scope of the present invention.

Firstly, it should be noted that the water used in the process of synthesizing TiO₂ nanocrystal in the examples of the present invention is preferably deionized water or distilled water.

It should be further noted that all of the reagents used in the examples of the present invention are commercially available or self-made, and there is no limitation on the sources thereof; for example:

K₂CO₃: AR grade, purchased from Tianjin Kemiou Chemical Reagent Co., Ltd.; Anatase-type TiO₂: AR grade, purchased from Tianjin Kemiou Chemical Reagent Co., Ltd.;

Hydrochloric acid: 36.5% (mass percent), purchased from Tianjin Kemiou Chemical Reagent Co., Ltd.;

Tetramethylammonium hydroxide (TMAOH): AR grade, purchased from Tianjin Kemiou Chemical Reagent Co., Ltd.

It should also be noted that all of devices used in the process of synthesizing TiO₂ nanocrystal in the examples of the present invention are commonly used devices in the art. They are commercially available and there is no specific limitation on them. The inventor believes that those skilled in the art can select appropriate experimental devices from the description of the technical solutions of the present invention. In the present invention, there is no specific limitation on the experimental devices, and there is no need to describe them in detail herein.

I. Synthesis of TiO₂ Nanocrystal

### Example 1

a) synthesis of a lamellar potassium tetratitanate:

13.821 g (0.1 mol) of K₂CO₃ and 31.960 g (0.4 mol) of anatase-type TiO₂ were weighed with a molar ratio of 1:4, placed into an agate mortar, mixed homogeneously, and ground sufficiently. Then, the mixture was transferred into a corundum crucible, which was then placed into a muffle furnace and heated at 900° C. for 24 hours, with a heating rate of 5° C./min, obtaining the lamellar fibrous potassium tetratitanate (K₂Ti₄O₉).

b) Synthesis of a tetratitanic acid:

10.0 g of K₂Ti₄O₉ synthesized in step a) was weighed, added into a beaker containing 1000 mL of 1 mol/L of the second hydrochloric acid solution, and magnetically stirred for three days at room temperature, with the second hydrochloric acid changed once a day, to allow K₂Ti₄O₉ to be completely converted to H₂Ti₄O₉. After performing the proton exchange reaction three times, the product was separated through centrifugation, and washed with deionized water four times. The centrifugation was repeated three times. Finally, the obtained sample was lyophilized, obtaining H₂Ti₄O₉.0.25H₂O.

c) Synthesis of the colloidal suspension of tetratitanic acid nanosheet:

3.5 g (about 0.01 mol) of H₂Ti₄O₉.0.25H₂O synthesized in step b) was weighed, and added into a polytetrafluoroethylene autoclave with an internal volume of 70 mL. Then 40 g (the mass fraction of 12.5%) of the second tetramethylammonium hydroxide solution was added. After sealing, the autoclave was placed into a high temperature rotary reaction furnace, and heated at 100° C. for 24 hours. After cooling to the room temperature, the product in the autoclave was transferred to a beaker. Then 360 mL of deionized water was added. The mixture was magnetically stirred at room temperature for 24 hours, left standing for 24 hours, and then filtered by suction, obtaining the colloidal suspension of tetratitanic acid nanosheet, i.e., the precursor.

d) Synthesis of a TiO₂ nanocrystal:

the pH value of the colloidal suspension of tetratitanic acid nanosheet synthesized in step c) was adjusted to 5.0 with 3 mol/L of the first hydrochloric acid solution and 1 mol/L of the first tetramethylammonium hydroxide solution. 40 mL of the pH-adjusted suspension of nanosheet was added into a polytetrafluoroethylene autoclave with an internal volume of 80 mL, which was then placed into a microwave oven and radiated by microwave at 180° C. for 1.5 hour. After cooling to room temperature, the product was separated through centrifugation, washed with deionized water four times, and then lyophilized, obtaining the anatase-type TiO₂ nanocrystal with {010} crystal facet exposed, the morphology of which was rhombus and cuboid.

### Example 2

a) Synthesis of a lamellar potassium tetratitanate:

14.512 g (0.105 mol) of K₂CO₃ and 31.960 g (0.4 mol) of anatase-type TiO₂ were weighed with a molar ratio of 1.05:4, placed into an agate mortar, mixed homogeneously, and ground sufficiently. Then the mixture was transferred into a corundum crucible, which was then placed into a muffle furnace and heated at 800° C. for 30 hours, with a heating rate of 2° C./min, obtaining the lamellar fibrous potassium tetratitanate (K₂Ti₄O₉).

b) Synthesis of a tetratitanic acid:

10.0 g of K₂Ti₄O₉ synthesized in step a) was weighed, added into a beaker containing 1000 mL of 0.7 mol/L of the second hydrochloric acid solution, and magnetically stirred for three days at room temperature, with the second hydrochloric acid changed once a day, to allow K₂Ti₄O₉ to be completely converted to H₂Ti₄O₉. After performing the proton exchange reaction three times, the product was separated through centrifugation, washed with deionized water four times. The centrifugation was repeated three times. Finally, the obtained product was lyophilized, obtaining H₂Ti₄O₉.1.9H₂O.

c) Synthesis of the colloidal suspension of tetratitanic acid nanosheet:

3.5 g (about 0.01 mol) of H₂Ti₄O₉.1.9H₂O synthesized in step b) was weighed, and added into a polytetrafluoroethylene autoclave with a volume of 70 mL. Then 40 g (the mass fraction of 25%) of the second tetramethylammonium hydroxide solution was added. After sealing, the autoclave was placed into a high temperature rotary reaction furnace, and heated at 90° C. for 30 hours. After cooling to the room temperature, the product in the autoclave was transferred to a beaker. Then 360 mL of deionized water was added. The mixture was magnetically stirred at room temperature for 24 hours, left standing for 24 hours, and then filtered by suction, obtaining the colloidal suspension of tetratitanic acid nanosheet, i.e., the precursor.

d) Synthesis of a TiO₂ nanocrystal:

the pH value of the colloidal suspension of tetratitanic acid nanosheet synthesized in step c) was adjusted to 7.0 with 2 mol/L of the first hydrochloric acid solution and 0.5 mol/L of the first tetramethylammonium hydroxide solution. 40 mL of the pH-adjusted suspension of nanosheet was added into a polytetrafluoroethylene autoclave with an internal volume of 80 mL, which was then placed into a microwave oven and radiated by microwave at 160° C. for 2 hours. After cooling to room temperature, the product was separated through centrifugation, washed with deionized water four times, and then lyophilized, obtaining the anatase-type TiO₂ nanocrystal with {010} crystal facet exposed, the morphology of which was fusiform.

### Example 3

a) Synthesis of a lamellar potassium tetratitanate:

15.203 g (0.11 mol) of K₂CO₃ and 31.960 g (0.4 mol) of anatase-type TiO₂ were weighed with a molar ratio of 1.1:4, placed into a agate mortar, mixed homogeneously, and ground sufficiently. Then the mixture was transferred into a corundum crucible, which was then placed into a muffle furnace and heated at 1000° C. for 20 hours, with a heating rate of 8° C./min, obtaining the lamellar fibrous potassium tetratitanate (K₂Ti₄O₉).

b) Synthesis of a tetratitanic acid:

10.0 g of K₂Ti₄O₉ synthesized in step a) was weighed, added into a beaker containing 1000 mL of 2 mol/L of the second hydrochloric acid solution, magnetically stirred for three days at room temperature, with the second hydrochloric acid changed once a day, to allow K₂Ti₄O₉ to be completely converted to H₂Ti₄O₉. After performing the proton exchange reaction three times, the product was separated through centrifugation, and washed with deionized water four times.

The centrifugation was repeated three times. Finally, the obtained sample was lyophilized, obtaining H₂Ti₄O₉.3H₂O.

c) Synthesis of the colloidal suspension of tetratitanic acid nanosheet:

3.5 g (about 0.01 mol) of H₂Ti₄O₉.3H₂O synthesized in step b) was weighed, and added into a polytetrafluoroethylene reactor with a volume of 70 mL. Then 50 g (the mass fraction of 15%) of the second tetramethylammonium hydroxide solution was added. After sealing, the reactor was placed into a high temperature rotary reaction furnace, and heated at 110° C. for 20 hours. After cooling to the room temperature, the product in the reactor was transferred to a beaker. Then 360 mL of deionized water was added. The mixture was magnetically stirred at room temperature for 24 hours, left standing for 24 hours, and then filtered by suction, obtaining the colloidal suspension of tetratitanic acid nanosheet, i.e., the precursor.

d) Synthesis of a TiO₂ nanocrystal:

the pH value of the colloidal suspension of tetratitanic acid nanosheet synthesized in step c) was adjusted to 13.0 with 1 mol/L of the first hydrochloric acid solution and 2 mol/L of the first tetramethylammonium hydroxide solution. 40 mL of pH-adjusted suspension of nanosheet was added into a polytetrafluoroethylene autoclave with an internal volume of 80 mL, which was then placed into a microwave oven and radiated by microwave at 200° C. for 1 hour. After cooling to room temperature, the product was separated through centrifugation, washed with deionized water four times, and then lyophilized, obtaining the anatase-type TiO₂ nanocrystal with {010} crystal facet exposed, the morphology of which was fusiform.

### Example 4

Step a) to step c) were the same as those in Example 1.

d) Synthesis of a TiO₂ nanocrystal:

the pH value of the colloidal suspension of tetratitanic acid nanosheet synthesized in step c) was adjusted to 5.0 with 3 mol/L of the first hydrochloric acid solution and 1 mol/L of the first tetramethylammonium hydroxide solution. 40 mL of the pH-adjusted suspension of nanosheet was added into a polytetrafluoroethylene autoclave with an internal volume of 70 mL. After sealing, the autoclave was placed into a high temperature rotary reaction furnace, and heated at 180° C. for 24 hours. After cooling to room temperature, the product was separated through centrifugation, washed with deionized water four times, and then lyophilized, obtaining the anatase-type TiO₂ nanocrystal with {010} crystal facet exposed, the morphology of which was rhombus and cuboid.

### Example 5

All steps were the same as those in Example 4, except that the pH value of the colloidal suspension of tetratitanic acid nanosheet in step d) was 6.2, obtaining the anatase-type TiO₂ nanocrystal with {010} crystal facet exposed, the morphology of which was rhombus and cuboid.

### Example 6

Step a) to step c) were the same as those in Example 2.

d) Synthesis of a TiO₂ nanocrystal:

the pH value of the colloidal suspension of tetratitanic acid nanosheet synthesized in step c) was adjusted to 7.0 with 2 mol/L of the first hydrochloric acid solution and 0.5 mol/L of the first tetramethylammonium hydroxide solution. 40 mL of the pH-adjusted suspension of nanosheet was added into a polytetrafluoroethylene autoclave with an internal volume of 70 mL. After sealing, the autoclave was placed into a high temperature rotary reaction furnace, and heated at 200° C. for 18 hours. After cooling to room temperature, the product was separated through centrifugation and washed with deionized water four times, and then lyophilized, obtaining the anatase-type TiO₂ nanocrystal with {010} crystal facet exposed, the morphology of which was fusiform.

### Example 7

All steps were the same as those in Example 6, except the pH value of the colloidal suspension of tetratitanic acid nanosheet in step d) was 9.0, obtaining the anatase-type TiO₂ nanocrystal with {010} crystal facets exposed, the morphology of which was rhombus and cuboid.

### Example 8

Step a) to step c) were the same as those in Example 3.

d) Synthesis of a TiO₂ nanocrystal:

the pH value of the colloidal suspension of tetratitanic acid nanosheet synthesized in step c) was adjusted to 13.0 with 1 mol/L of the first hydrochloric acid solution and 2 mol/L of the first tetramethylammonium hydroxide solution. 40 mL of the pH-adjusted suspension of nanosheet was added into a polytetrafluoroethylene autoclave with an internal volume of 70 mL. After sealing, the autoclave was placed into a high temperature rotary reaction furnace, and heated at 140° C. for 30 hours. After cooling to room temperature, the product was separated through centrifugation, washed with deionized water four times, and then lyophilized, obtaining the anatase TiO₂ nanocrystal with {010} crystal facet exposed, the morphology of which was fusiform.

In the process of synthesizing TiO₂ nanocrystal in the above Examples 1 to 8, the parameters related to the centrifugation can be as follows: the rotation speed for centrifugation was 8000 rpm (revolution per minute), and the centrifugation period was 10 minutes.

It should be noted that the parameters related to the centrifugation used in the examples of the present invention are provided only for those skilled in the art to better understand the method for synthesizing TiO₂ nanocrystal, and do not mean that the technical solutions of the present invention can only be achieved by using those exemplary parameters. It is feasible for those skilled in the art to adjust these parameters according to the practical conditions. In the present invention, there is no specific limitation on them herein.

In the process of synthesizing TiO₂ nanocrystal in the above Examples 1 to 8, the process of lyophilizing was as follows: the sample was placed in a glass bottle dedicated for freezing, which was then mounted in a freezer. The rotation button was turned on, to allow the sample-containing aqueous solution to rotate and be frozen into ice in the freezer. The temperature of the liquid in the freezer was −15° C. to −30° C. The freezing period for the sample was generally 30 minutes to allow the sample to be frozen into ice. The period would be a little longer when the amount of the aqueous solution in the sample was large. After the product was frozen into ice, the rotation button and the freezer were turned off. The freezing bottle was took out and mounted on a drier. The vacuum pump was turned on to pump to a gauge pressure of about −0.09 MPa. The bottle was dried under vacuum condition for 24 hours.

Similarly, the parameters related to lyophilization used in the examples were only provided for those skilled in the art to better understand the method for synthesizing TiO₂ nanocrystal. It is feasible for those skilled in the art to adjust these parameters according to the practical conditions. In the present invention, there is no specific limitation on them herein.

II. Characterization of the TiO₂ Nanocrystal

1. XRD (X-Ray Diffraction) Analysis

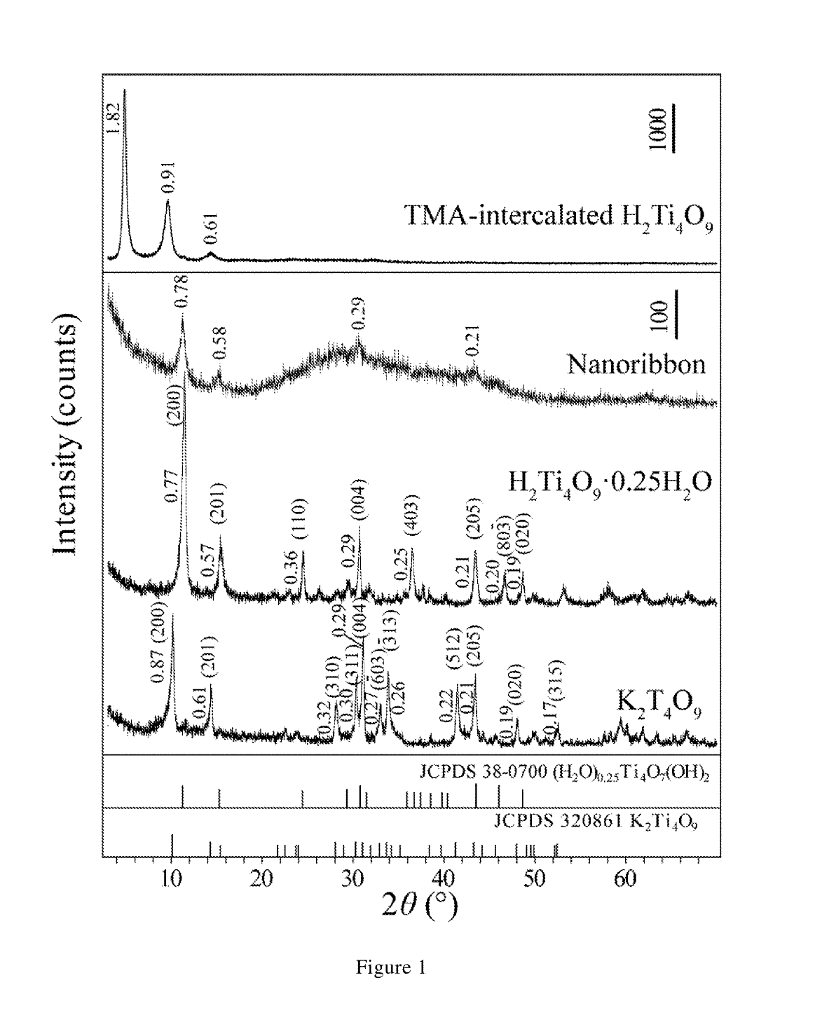

(a) XRD characterization were performed with SHIMADZU XRD-6100 diffractometer on the potassium tetratitanate (K₂Ti₄O₉) synthesized in step a), the tetratitanic acid (H₂Ti₄O₉.0.25H₂O) synthesized in step b), the tetramethylammonium ion (TMA⁺) intercalated tetratitanic acid (TMA⁺-intercalated H₂Ti₄O₉), and the nanoribbon-like tetratitanic acid exfoliated from the colloidal suspension of tetratitanic acid nanosheet synthesized in step c) in Example 1 of the present invention, respectively, wherein the diffraction angle (2θ) range for collected data was 3-70°, the scanning rate was 5°/min, and the acceleration voltage and the current applied were 40 kV and 30 mA respectively. The results were as shown in FIG. 1.

It can be seen from FIG. 1 that, the basal spacing of (200) crystal facet in K₂Ti₄O₉ reduced from 0.87 nm to 0.77 nm, which corresponding to the basal spacing of H₂Ti₄O₉.0.25H₂O, indicating that K₂Ti₄O₉ was protonated successfully. With the insertion of TMA⁺ ion, the basal spacing of (200) crystal facet thereof increased to 1.82 nm, indicating that TMA⁺ was exchanged with H⁺, and inserted into the interlayer of tetratitanic acid successfully. The TMA⁺-inserted tetratitanic acid was dissolved in water, and stirred for 3 days, thus obtaining the colloidal suspension of corresponding nanosheet. XRD characterization was performed after the centrifugation of the colloidal suspension of TMA⁺-inserted tetratitanic acid nanosheet. It was found that a halo occurred in the 2θ range of 20-40°, indicating that a exfoliation reaction of the lamellar H₂Ti₄O₉ occurred successfully and H₂Ti₄O₉ was exfoliated into nanosheet. In the meantime, the diffraction peaks with weaker peak intensity occurred at the basal spacings of 0.78 nm, 0.58 nm and 0.29 nm in the XRD patterns, indicating that some of the nanosheets formed by exfoliating occurred were re-arranged after centrifugation, and were stacked into tetratitanic acid again. As mentioned above, the corresponding target product was synthesized through step a) to step c) in Example 1. Since the products obtained by the step a) to step c) in Examples 2 to 8 were the same as that in Example 1, reference can be made to FIG. 1 for their XRD patterns, without detailed description herein.

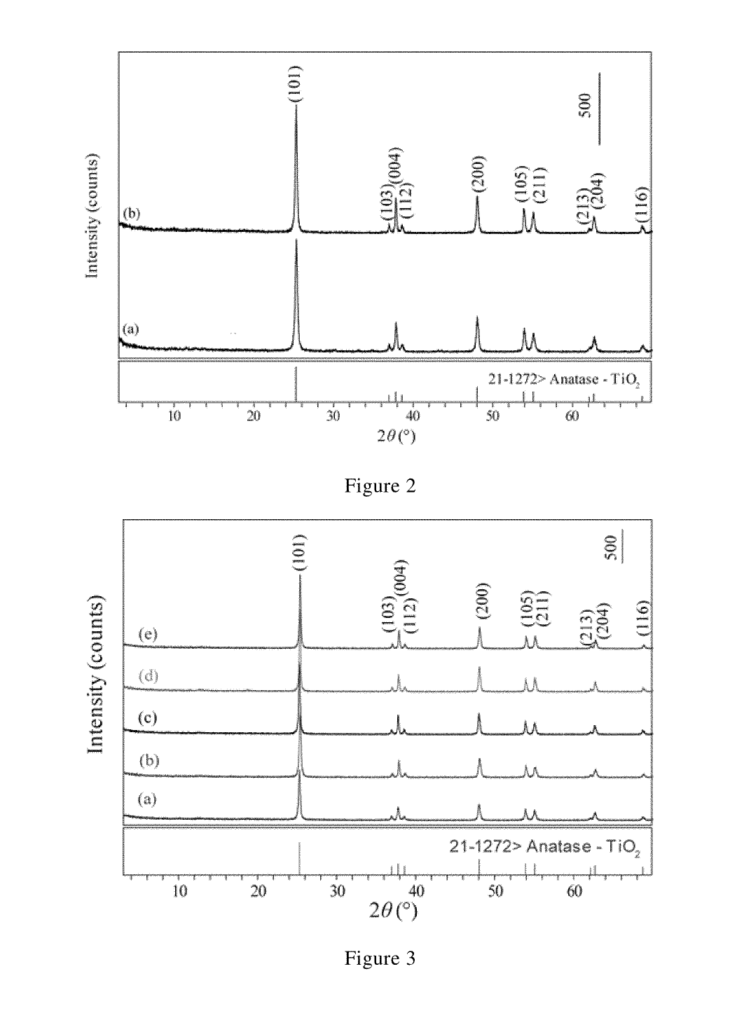

(b) XRD characterization was performed with SHIMADZU XRD-6100 diffractometer on the TiO₂ nanocrystals synthesized in Examples 1 and 2 of the present invention, respectively, wherein the diffraction angle (2θ) range for collected data was 3-70°, the scanning rate was 5°/min, and the acceleration voltage and the current applied were 40 kV and 30 mA respectively. The results were as shown in FIG. 2.

It can be seen from FIG. 2 that, the TiO₂ nanocrystals synthesized in Examples 1 and 2 were both anatase-type TiO₂, corresponding to standard card 21-1272 of JCPDS. It can be seen from the XRD patterns that the measured intensity of diffraction peak was higher at pH=7.0, indicating that the particle size of the synthesized TiO₂ nanocrystal was larger and the crystallinity was higher at pH=7.0. Since the TiO₂ nanocrystal synthesized in Example 3 was same as the TiO₂ nanocrystals synthesized in Examples 1 and 2, reference can be made to FIG. 2 for their XRD patterns, without detailed description herein.

As mentioned above, anatase-type TiO₂ nanocrystal can be synthesized with the methods used in Examples 1 to 3.

(c) XRD characterization was performed with SHIMADZU XRD-6100 diffractometer on the TiO₂ nanocrystals synthesized in Examples 4 to 8 of the present invention, respectively, wherein, the diffraction angle (2θ) range for collected data was 3-70°, the scanning rate was 5°/min, and the acceleration voltage and the current applied were 40 kV and 30 mA respectively. The results were as shown in FIG. 3.

It can be seen from FIG. 3 that, the TiO₂ nanocrystals synthesized in Examples 4 to 8 were all anatase-type TiO₂, corresponding to standard card 21-1272 of JCPDS. It can be seen from these five XRD spectrograms that the measured intensity of diffraction peak increased and peak width narrowed with the increase of pH value, indicating that the particle size of the synthesized TiO₂ nanocrystal was larger and the crystallinity was higher.

2. Field Emission Scanning Electron Microscope (FE-SEM) Analysis

(a) The morphology and microstructure of the TiO₂ nanocrystals synthesized in Examples 1, 2 and 3 of the present invention were analyzed with HITACHI S-90X type field emission scanning electron microscope. The sample was prepared as follows: the sample was dissolved in deionized water and subjected to ultrasonication; and then one drop of the sample was dropped on a silicon plate. During the measurement, the acceleration voltage was 15 kV, and the applied current was 10 μA. The results were as shown in FIG. 4.

It can be seen from FIG. 4 that, the morphology of the anatase-type TiO₂ nanocrystal synthesized in Example 1 was cuboid and rhombus, and the average particle size thereof was about 50 nm. The morphology of the anatase-type TiO₂ nanocrystals synthesized in Example 2 and 3 were fusiform, and the average particle sizes thereof were about 150 nm and about 480 nm, respectively.

It can be known from FIG. 4 that pH value has an important influence on the morphology and size of particles.

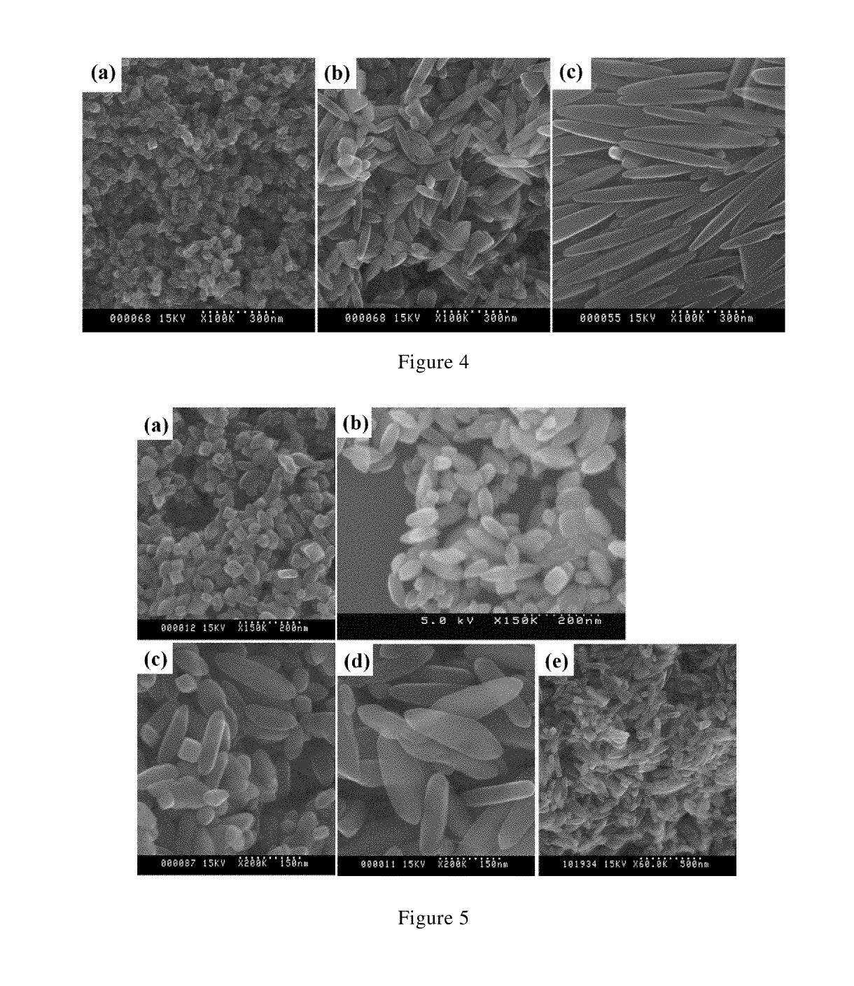

(b) The morphology and microstructure of the TiO₂ nanocrystals synthesized in Examples 4 to 8 of the present invention were analyzed with HITACHI S-90X type field emission scanning electron microscope. The sample was prepared as follows: the sample was dispersed into deionized water and subjected to ultrasonication, and then one drop of the sample was dropped on a silicon plate. During the measurement, the acceleration voltage was 15 kV, and the applied current was 10 μA. The results were as shown in FIG. 5.

It can be seen from FIG. 5(a) that, the morphology of the anatase-type TiO₂ nanocrystal synthesized in Example 4 (pH=5.0) was cuboid and rhombus, and the average particle size thereof was about 50 nm. It can be seen from FIGS. 5(b) to 5(e) that, the morphologies of the anatase-type TiO₂ nanocrystals synthesized in Examples 5 to 8 (pH>5) were fusiform, and the average particle sizes thereof were also increased with the increase of pH value. This suggests that pH value has an important influence on the morphology and size of particles.

3. Transmission Electron Microscope (TEM) Analysis

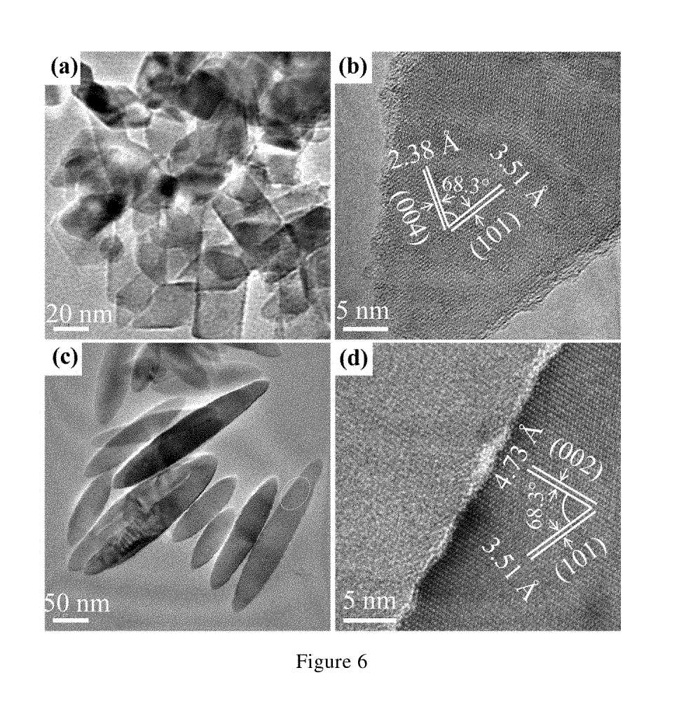

Transmission electron microscope (TEM) and high resolution transmission electron microscope (HR-TEM) measurement were performed on the TiO₂ nanocrystal synthesized in Example 1. The test conditions were as follows: the acceleration voltage was 300 kV, and the sample was prepared on a standard copper grid loaded with carbon film. The results were as shown in FIGS. 6(a) to 6(b).

Transmission electron microscope (TEM) and high resolution transmission electron microscope (HR-TEM) measurement were performed on the TiO₂ nanocrystal synthesized in Example 2. The test conditions were as follows: the acceleration voltage was 300 kV, and the sample was prepared on a standard copper grid loaded with carbon film. The results were as shown in FIGS. 6(c) to 6(d).

It can be seen from FIG. 6(a) that, the morphology of the synthesized anatase-type TiO₂ nanocrystal was cuboid and rhombus under the condition of pH=5.0. In FIG. 6(b), the fringe spacings were 3.51 Å and 2.38 Å, corresponding to (101) and (004) crystal facets of anatase-type TiO₂ respectively. The included angle between these two crystal facets was 68.3°, in accordance with the result calculated according to the (101) and (004) crystal facet constants of anatase-type TiO₂. It can be seen from FIG. 6(c) that, the morphology of the synthesized anatase-type TiO₂ nanocrystal was fusiform under the condition of pH=7.0. In FIG. 6(d), the fringe spacings were 3.51 Å and 4.73 Å, corresponding to (101) and (002) crystal facets of anatase-type TiO₂ respectively, with an included angle of 68.3°. It can be seen from FIGS. 6(b) and 6(d) that, the exposed crystal facets of the anatase-type TiO₂ nanocrystals synthesized in the present invention were both {010} crystal facet.

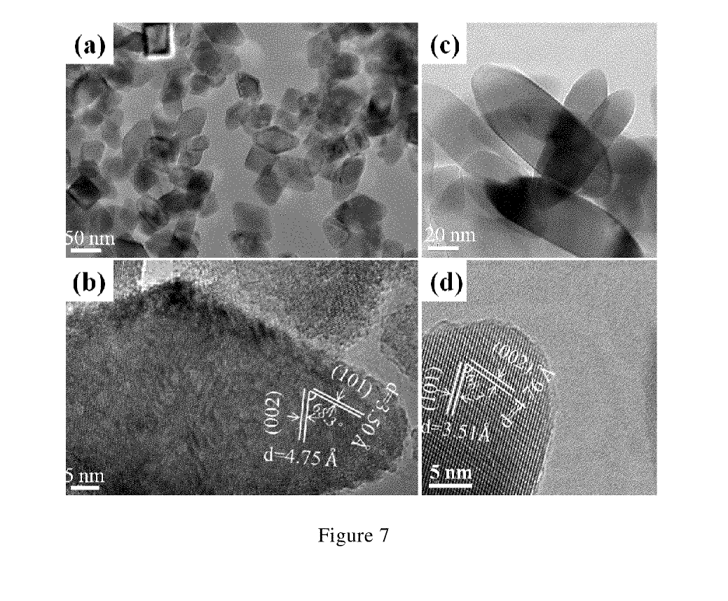

Transmission electron microscope (TEM) and high resolution transmission electron microscope (HR-TEM) measurement were performed on the TiO₂ nanocrystal synthesized in Example 5. The test conditions were as follows: the acceleration voltage was 300 kV, and the sample was prepared on a standard copper grid loaded with carbon film. The results were as shown in FIGS. 7(a) to 7(b).

Transmission electron microscope (TEM) and high resolution transmission electron microscope (HR-TEM) measurement were performed on the TiO₂ nanocrystal synthesized in Example 6, the test conditions were as follows: the acceleration voltage was 300 kV, preparing sample on the standard copper grid loaded with carbon film. The results were shown as FIG. 7(c) to FIG. 7(d).

It can be seen from FIG. 7(a) that, the morphology of the synthesized anatase-type TiO₂ nanocrystal was cuboid and rhombus under the condition of pH=5.0. In FIG. 7(b), the fringe spacings were 3.50 Å and 4.75 Å, corresponding to (101) and (002) crystal facets of anatase-type TiO₂ respectively, The included angle between these two crystal facets was 68.3°, in accordance with the result calculated according to the (101) and (002) crystal facet constants of anatase-type TiO₂. It can be seen from FIG. 7(c) that, the morphology of the synthesized anatase-type TiO₂ nanocrystal was fusiform under the condition of pH=6.2. In FIG. 7(d), the fringe spacings were 3.51 Å and 4.76 Å, corresponding to (101) and (002) crystal facets of anatase-type TiO₂ respectively, with an included angle of 68.3°. It can be seen from FIGS. 7(b) and 7(d) that, the exposed crystal facets of the anatase-type TiO₂ nanocrystals synthesized in the present invention were both {010} crystal facet.

It can be known from the above characterization and analysis that the anatase-type TiO₂ nanocrystal with {010} crystal facet exposed can be synthesized with the synthesis method provided in the present invention.

III. Property Analysis for the TiO₂ Nanocrystal

Since the anatase-type TiO₂ nanocrystals with rhombus and cuboid morphology and the anatase-type TiO₂ nanocrystal with fusiform morphology were synthesized respectively in Examples 1 to 8 of the present invention, property analysis for the anatase-type TiO₂ nanocrystal with two kinds of morphologies were performed respectively herein, wherein, Example 1 was used as the example of the anatase-type TiO₂ nanocrystal with rhombus and cuboid morphology, and Example 2 was used as the example of the anatase-type TiO₂ nanocrystal with fusiform morphology. Since the anatase-type TiO₂ nanocrystals synthesized in other examples were the same as those in Examples 1 and 2 respectively, reference can be made to Example 1 or 2 for their properties.

1. Photocatalytic Experiment

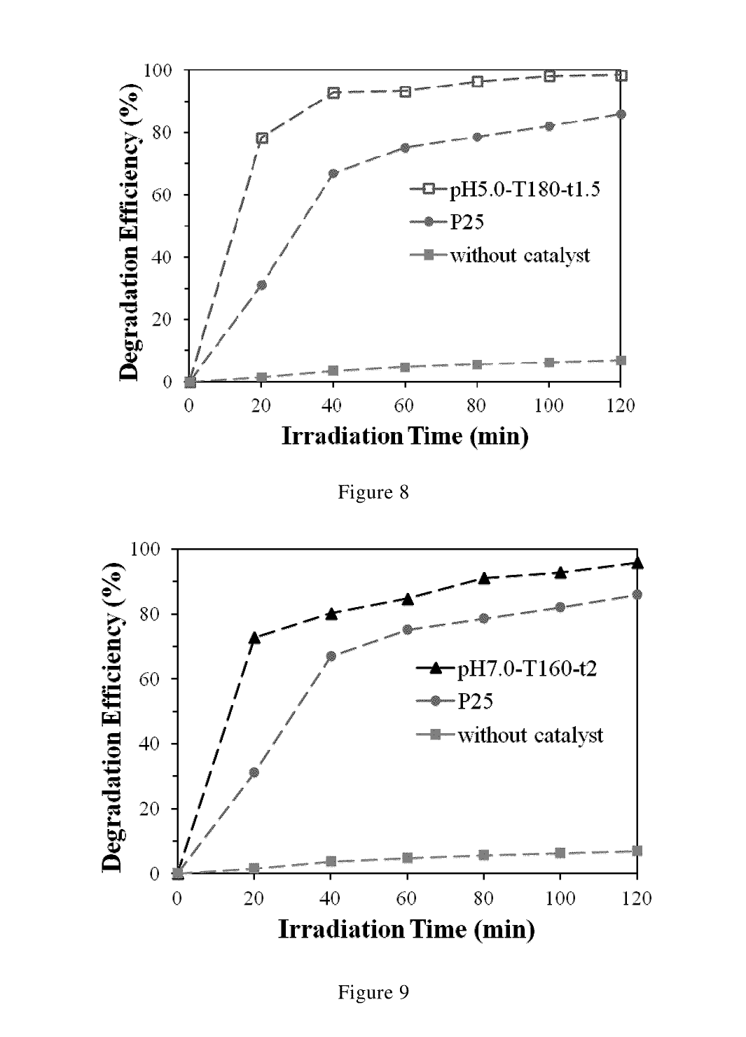

50 mg of the anatase-type TiO₂ nanocrystal synthesized in Examples 1 and 2 were weighed, added into a 150 mL Erlenmeyer flask respectively. Then 100 mL of 10 mg/L methyl blue solution was added into each Erlenmeyer flask. Ultrasonication was performed for 2 hours to disperse these two samples homogeneously. Before irradiation, the suspension in these two Erlenmeyer flasks was stirred vigorously for 30 min in dark to allow the dye to reach adsorption/desorption equilibrium at the surface of TiO₂ nanocrystal. Then, the suspension in these two Erlenmeyer flasks was irradiated with a 250 W UV lamp under stirring. The emission wavelength of the UV lamp was 365 nm, and the distance from the methyl blue solution was 80 cm. 3 mL of suspension was taken from these two Erlenmeyer flasks every 20 min respectively and centrifuged to remove TiO₂ nanocrystal. The degradation rate of methyl blue was determined by measuring the concentration change of methyl blue solution before and after the UV lamp irradiation with TU-1901 spectrophotometer. For comparison, a commercial Degussa P25 (52.50 m²/g, 80% of anatase and 20% of rutile) was determined under the same condition. The test results were as shown in FIGS. 8 and 9 respectively.

FIG. 8 is the characteristic curve of degradation efficiency versus irradiation time for the TiO₂ nanocrystal synthesized in Example 1. It can be seen from the figure that, at 120 min, the degradation efficiency for the anatase-type TiO₂ nanocrystal synthesized in Example 1 to methyl blue was 99%, and the degradation efficiency of P25 to methyl blue was 86%. Therefore, the degradation efficiency of the anatase-type TiO₂ nanocrystal synthesized in Example 1 to methyl blue was much higher than that of Degussa P25 to methyl blue.

FIG. 9 is the characteristic curve of degradation efficiency versus irradiation time of the TiO₂ nanocrystal synthesized in Example 2. It can be seen from the figure that, at 120 min, the degradation efficiency of the anatase-type TiO₂ nanocrystal synthesized in Example 1 to methyl blue was 96%, and the degradation efficiency of P25 to methyl blue was 86%. Therefore, the degradation efficiency of the anatase-type TiO₂ nanocrystal synthesized in Example 2 to methyl blue was much higher than that of Degussa P25 to methyl blue.

In summary, the degradation efficiency of the anatase-type TiO₂ nanocrystal with {010} crystal facet exposed synthesized in the examples of the present invention to methyl blue were both higher than that of Degussa P25 to methyl blue, whether the morphology was rhombus and cuboid or fusiform. This suggests that, the anatase-type TiO₂ nanocrystal with {010} crystal facet exposed synthesized in the examples of the present invention has good photocatalytic property.

2. Photovoltaic Property Measurement

0.5 g of the anatase-type TiO₂ nanocrystals synthesized in Examples 1 and 2 were weighed, and added into a glass bottle respectively. Then 2.5 g of ethanol, 2.0 g of α-terpineol, 1.4 g of 10 wt % solution of ethyl cellulose 10 and 1.1 g of 10 wt % solution of ethyl cellulose 45 were added into these two glass bottles respectively. Then ultrasonic treatment was performed on both of the two glass bottles for 5 min. The samples were ball-milled at room temperature for 3 days, and finally rotary evaporated in a vacuum rotary evaporator to remove ethanol, obtaining the TiO₂ slurries of Examples 1 and 2 respectively.

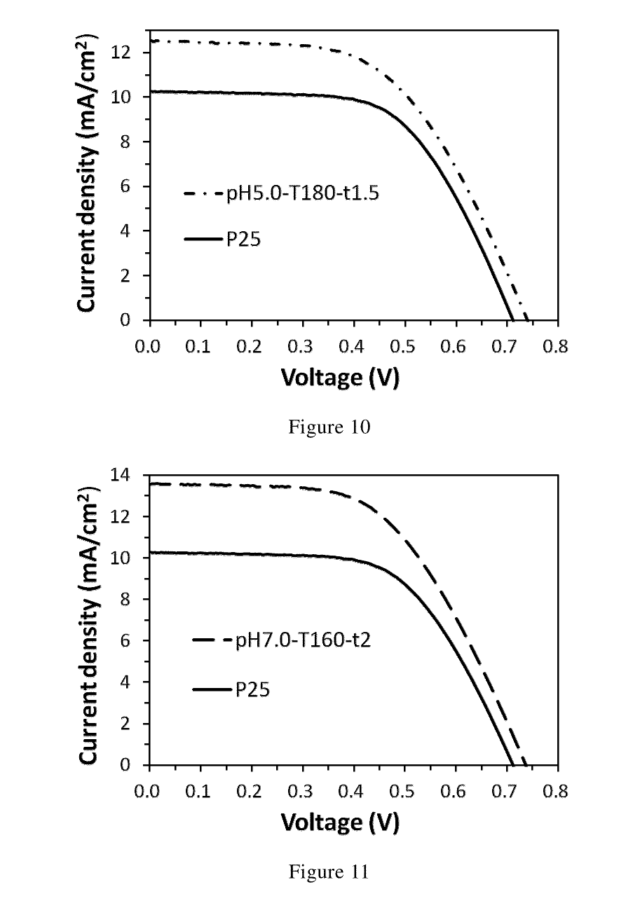

FTO glass (length×width×height=50 mm×50 mm×2.2 mm, the surface resistivity: ˜7 Ω/sq, produced by Aldrich) was ultrasonically treated with deionized water for 5 min, and then with ethanol for another 5 min. The washed FTO glass was immersed into 0.1 M Ti(OC₃O₇)₄ organic titanium solution for a few seconds, and then calcinated in a high temperature furnace for 60 min. Porous TiO₂ thin-film electrode was produced by coating TiO₂ slurries of Examples 1 and 2 onto FTO conductive glass by using doctor-blade method respectively. The thickness of the thin film was controlled by the thickness of the tape used. After coating TiO₂ slurries of Example 1 and 2 onto the FTO conductive glass respectively, calcination was performed at 315° C. in a high temperature furnace for 15 min. The operation as above-mentioned was repeated several times until the desired film thickness was achieved. And then calcination was performed at 450° C. in a high temperature furnace for 30 min. After cooling to room temperature, the FTO glass was again immersed into 0.1 M Ti(OC₃O₇)₄ organic titanium solution for a few seconds, and then calcinated in a high temperature furnace for 60 min. When the temperature was decreased to 80° C., the FTO glass was taken out, quickly immersed into a mixed solution of acetonitrile and tertiary butanol containing 3×10⁻⁴ mol/L N719, and left standing in the dark at room temperature for 24 hours to allow the dyes to be adsorbed on the TiO₂ electrode. Pt counter electrode was produced by immersing FTO conductive glass into an isopropanol solution containing 0.5 mM H₂PtCl₆, taking it out after a few minutes, and then calcinating it at 400° C. in a high temperature furnace for 20 min. The electrolyte solution was injected into the interspace between the two electrodes via capillary effect, assembling into a dye-sensitized solar cell with a sandwich structure. The electrolyte solution was made of a mixing solution of acetonitrile and valeronitrile (volume ratio=85%:15%) containing 0.60 mol/L 1-butyl-3-methylimidazolium iodide, 0.10 mol/L guanidine thiocyanate and 0.50 mol/L 4-tert-butylpyridine. A photoanode of Degussa P25 TiO₂ produced by the same method was assembled into a cell, so as to compare with the above cell. The test results were as shown in FIGS. 10 and 11.

FIG. 10 is the characteristic curve of photocurrent versus voltage of Example 1 when the membrane thickness was 13.8 μm. It can be seen from the figure that, the anatase-type TiO₂ nanocrystal which preferentially exposes {010} crystal facet has a photocurrent of 12.6 mA/cm³ and a conversion efficiency of 5.09%, which are obviously better than the photocurrent of 10.3 mA/cm³ and the conversion efficiency of 4.37% respectively for P25.

FIG. 11 is the characteristic curve of photocurrent versus voltage of Example 2 when the membrane thickness was 16.4 μm. It can be seen from the figure that, the anatase-type TiO₂ nanocrystal which preferentially exposed {010} crystal facet has a photocurrent of 13.6 mA/cm³ and a conversion efficiency of 5.48%, which are obviously better than the photocurrent of 10.3 mA/cm³ and the conversion efficiency of 4.37% respectively for P25.

The present invention employs a novel method to synthesize anatase-type TiO₂ nanocrystal which preferentially exposes {010} crystal facet. This method has advantages of low cost, no pollution, simple synthesizing process, strong controllability, short production period, and good reproducibility. This method meets the requirement of “green chemistry” and is suitable for industrial production. The anatase-type TiO₂ nanocrystal with {010} crystal facet prepared by using the method provided in the present invention has high purity and homogeneous size distribution. And it has significantly improved catalytic property and photovoltaic property when used for the degradation of methyl blue solution and used in dye-sensitized solar cell, compared to the commercial Degussa P25 TiO₂ (52.50 m²/g, 80% of anatase and 20% of rutile).

A method for synthesizing TiO₂ nanocrystal provided in the present invention is described in detail above. Specific examples are used for explaining the theory and embodiments of the present invention. The description of the above examples is only used for better understanding the method and main concept of the present invention. It should be noted that, for those of ordinary skill in the art, some changes and modifications can be made without departing from the theory of the present invention, and these changes and modifications will fall into the protection scope of the claims of the present invention.

1. A method for synthesizing TiO₂ nanocrystal, characterized in that, the method comprises the following steps:
adjusting the pH value of a colloidal suspension of tetratitanic acid nanosheet as a precursor to 5-13; and
subjecting the precursor with a pH of 5-13 to a hydrothermal reaction to obtain the TiO₂ nanocrystal.

2. The method according to claim 1, characterized in that, after the hydrothermal reaction, the obtained product is separated, washed, filtered and dried.

3. The method according to claim 1, characterized in that, the step of subjecting the precursor with a pH of 5-13 to a hydrothermal reaction is as follows:
applying a microwave radiation to the precursor with a pH of 5-13 for 1 to 2 hours at 160 to 200° C.; or
heating the precursor with a pH of 5-13 to 140 to 200° C. and maintaining the temperature for 18 to 30 hours.

4. The method according to claim 1, characterized in that, the pH value of the precursor is adjusted with a first hydrochloric acid solution and a first tetramethylammonium hydroxide solution, wherein the concentration of the first hydrochloric acid solution is 1 mol/L to 3 mol/L, and the concentration of the first tetramethylammonium hydroxide solution is 0.5 mol/L to 2 mol/L.

5. The method according to claim 1, characterized in that, the method for preparing the colloidal suspension of tetratitanic acid nanosheet as precursor comprises the following steps:
a) synthesizing a lamellar potassium tetratitanate:
K₂CO₃ and anatase-type TiO₂ as raw materials are homogeneously mixed, heated to 800 to 1000° C., and reacted for 20 to 30 hours, obtaining the lamellar potassium tetratitanate, wherein the molar ratio of the K₂CO₃ and anatase-type TiO₂ is (1-1.1):4;
b) synthesizing a tetratitanic acid:
the potassium tetratitanate synthesized in step a) is dissolved in a second hydrochloric acid solution to perform a proton exchange reaction, the obtained product is separated after the completion of the reaction, and then the obtained product is washed, filtered and dried, obtaining the tetratitanic acid; and
c) synthesizing the colloidal suspension of tetratitanic acid nanosheet:
the tetratitanic acid synthesized in step b) is added into a second tetramethylammonium hydroxide solution, obtaining a mixed solution; the mixed solution is subjected to reaction for 20 to 30 hours at 90 to 110° C.; after the completion of the reaction, the obtained product is mixed with water, stirred, and then filtered after standing, obtaining the colloidal suspension of tetratitanic acid nanosheet as precursor.

6. The method according to claim 5, characterized in that, in step a), after mixing K₂CO₃ and anatase-type TiO₂ homogeneously and prior to heating to 800 to 1000° C., it further comprises grinding sufficiently.

7. The method according to claim 5, characterized in that, in step a), the rate of the heating is 2° C./min to 8° C./min.

8. The method according to claim 5, characterized in that, in step b), the concentration of the second hydrochloric acid solution is 0.7 mol/L to 2 mol/L.

9. The method according to claim 5, characterized in that, in step b), the process of dissolving the potassium tetratitanate synthesized in step a) in a second hydrochloric acid to perform a proton exchange reaction is as follows:
the potassium tetratitanate synthesized in step a) is dissolved in the second hydrochloric acid, and stirred for 3 to 5 days, with the second hydrochloric acid changed once a day.

10. The method according to claim 5, characterized in that, in step c), the mass ratio of tetratitanic acid and tetramethylammonium hydroxide is 1:(1.2-3).
